(19) United States
(12) Patent Application Publication
(10) Pub. No.: US 2015/0027762 A1
(43) Pub. Date: Jan. 29, 2015

(54) PRINTED CIRCUIT BOARD

(71) Applicant: SAMSUNG ELECTRO-MECHANICS CO., LTD., Suwon (KR)

(72) Inventors: Yong Sang SHIN, Busan (KR); Joo Sung PARK, Busan (KR)

(73) Assignee: SAMSUNG ELECTRO-MECHANICS CO., LTD., Suwon (KR)

(21) Appl. No.: 14/444,144

(22) Filed: Jul. 28, 2014

(30) Foreign Application Priority Data
Jul. 29, 2013 (KR) 10-2013-0089495

(51) Int. Cl. H05K 1/02; H05K 1/11; H05K 1/09

(52) U.S. Cl. CPC H05K 1/0271; H05K 1/09; H05K 1/0298; H05K 1/114
USPC 174/257; 174/263

(57) ABSTRACT

Disclosed herein is a printed circuit board capable of increasing reliability by decreasing stress between an insulating layer and solder balls. The printed circuit board includes: an insulating layer part including circuit patterns and connecting lands having solder balls seated thereon and including a plurality of insulating layers; a plurality of connecting pads and non-connecting pads formed at the insulating layer part; and a plurality of reinforcing vias formed in the non-connecting pads and reinforcing a close adhesion state between the insulating layer part and the non-connecting pads.

### CROSS REFERENCE(S) TO RELATED APPLICATIONS

This application claims the foreign priority benefit under 35 U.S.C. Section 119 of Korean Patent Application Serial No. 10-2013-0089495, entitled “Printed Circuit Board” filed on Jul. 29, 2013, which is hereby incorporated by reference in its entirety into this application.

### BACKGROUND OF THE INVENTION

1. Technical Field

The present invention relates to a printed circuit board, and more particularly, to a printed circuit board capable of increasing reliability by decreasing stress between an insulating layer and a solder ball.

2. Description of the Related Art

Generally, in accordance with slimness and lightness of electronic apparatuses of an information technology (IT) field including a cellular phone, a size of a board has been limited and a multi-function of the electronic apparatus has been demanded. Therefore, it is required to mount electronic components for implementing more functions in a limited area of the board.

However, since a mounting area of the electronic components may not be sufficiently secured due to the limitation of the size of the board, a technology of inserting electronic components such as an active device, for example, an integrated circuit (IC), a semiconductor chip, a passive device, and the like, in the board has been demanded. Recently, a technology of embedding the active device and the passive device in the same layer or stacking the active device and the passive device and then embedding the stacked active device and passive device in a board has been developed.

Generally, in a method of manufacturing a printed circuit board in which components are embedded, a cavity is formed in a core of a board, and various devices and electronic components such as an IC, a semiconductor chip, and the like, are inserted into the cavity. Then, a resin material such as prepreg, or the like, is applied into the cavity and onto the core into which the electronic components are inserted to fix the electronic components and form an insulating layer. A via hole or a through-hole is formed in the insulating layer and a circuit is formed by plating to allow the electronic components to be electrically conducted to the outside of the board.

Here, circuit patterns are formed in and on the via hole and the through-hole by the plating and are used as an electrical connection unit with the electronic components embedded in the board, and the insulating layers are sequentially stacked on upper and lower surfaces of the board, thereby making it possible to manufacture a multilayer printed circuit board in which the electronic components are embedded.

However, in the case in which impact is applied to the electronic components or warpage is generated due to a difference in thermal expansion in a manufacturing process in the state in which the electronic components are mounted in the printed circuit board having a plurality of insulating layers stacked therein, significant stress is applied to solder balls electrically connecting the electronic components and the insulating layers to each other, such that a crack is generated between the solder balls and the insulating layers.

As the number of chips per unit area of the printed circuit board is increased, the generation of the crack is intensified. In addition, the above-mentioned problems cannot but be intensified since a thickness of the board has been gradually decreased.

[Related Art Document]

[Patent Document]

(Patent Document 1) Cited Reference: Japanese Patent Laid-Open Publication No. 2004-247415

### SUMMARY OF THE INVENTION

An object of the present invention is to provide a printed circuit board capable of increasing durability and reliability of a product by forming a reinforcing via at a non-connecting land so that an insulating layer and a connecting pad may be maintained in the state in which they are tightly coupled to each other.

According to an exemplary embodiment of the present invention, there is provided a printed circuit board including: an insulating layer part including circuit patterns and connecting lands having solder balls seated thereon and including a plurality of insulating layers; a plurality of connecting pads and non-connecting pads formed at the insulating layer part; and a plurality of reinforcing vias formed in the non-connecting pads and reinforcing a close adhesion state between the insulating layer part and the non-connecting pads.

The reinforcing vias may be formed at positions at which interlayer electrical conduction is not made among the plurality of connecting pads. The insulating layer part may include a copper clad laminate (CCL) including an insulating material and copper foils formed on both surfaces of the insulating material and include a plurality of stacked insulating layers that are not the CCL.

The reinforcing via positioned at the center of the non-connecting pad and the reinforcing vias positioned along a circumferential surface of the non-connecting pad may be formed in opposite directions or the same direction.

The reinforcing vias may be formed at the non-connection pads at which interlayer conduction is not made.

### BRIEF DESCRIPTION OF THE DRAWINGS

FIG. 1 is an illustrative diagram showing a lateral cross section of a printed circuit board according to an exemplary embodiment of the present invention;

FIG. 2 is a plan view showing the printed circuit board according to the exemplary embodiment of the present invention when being viewed from the top of an insulating layer; and

FIG. 3 is an illustrative diagram showing a printed circuit board according to another exemplary embodiment of the present invention.

### DESCRIPTION OF THE PREFERRED EMBODIMENTS

Hereinafter, exemplary embodiments of the present invention will be described in detail with reference to the accompanying drawings.

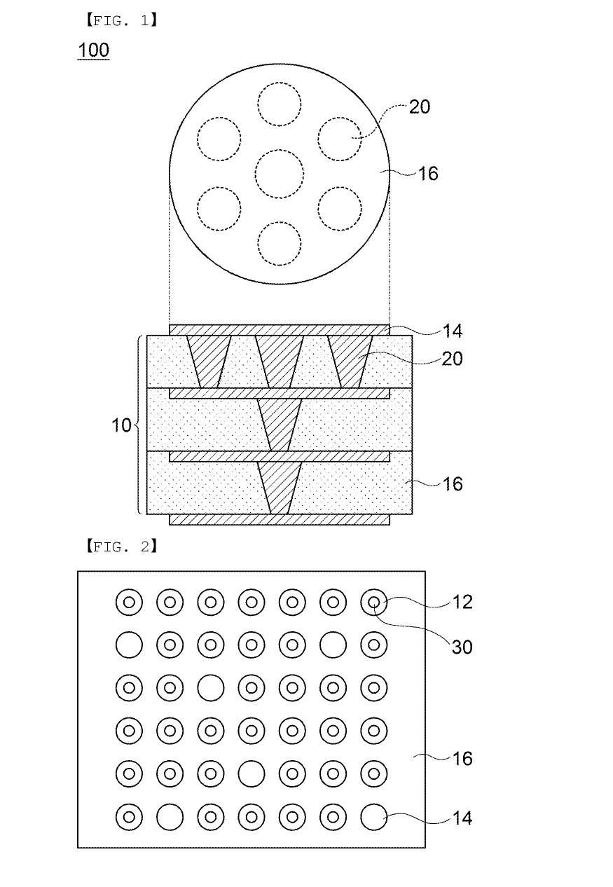

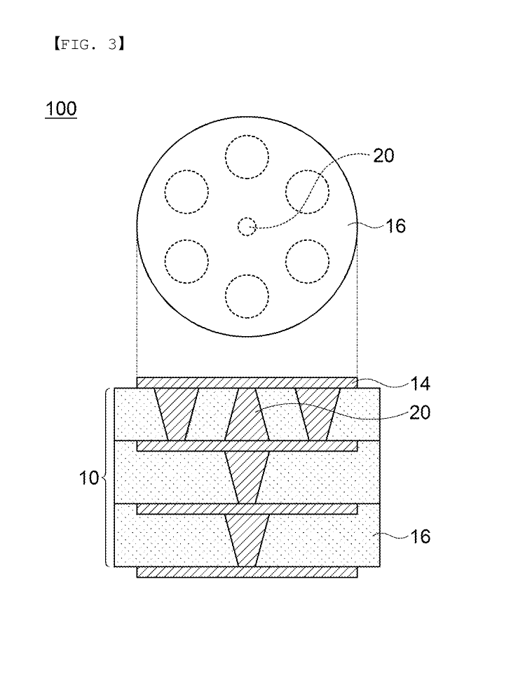

FIG. 1 is an illustrative diagram showing a lateral cross section of a printed circuit board according to an exemplary embodiment of the present invention; FIG. 2 is a plan view showing the printed circuit board according to the exemplary embodiment of the present invention when being viewed from the top of an insulating layer; and FIG. 3 is an illustrative diagram showing a printed circuit board according to another exemplary embodiment of the present invention.

As shown, the printed circuit board 100 according to the exemplary embodiment of the present invention is configured to include an insulating layer part 10 including a plurality of insulating layers, a plurality of connecting pads 12 and non-connecting pads 14 formed at the insulating layer part 10, and a plurality of reinforcing vias 20 formed in the non-connecting pads 14 and reinforcing a close adhesion state between the insulating layer part 10 and the non-connecting pads 14.

The insulating layer part 10 in which at least one pair of insulating layers 16 having the circuit patterns (not shown) formed thereon are stacked may include a plurality of insulating layers 16 built-up therein according to a specification of an electronic product in order to implement a more slim structure.

Particularly, recently, a thickness of an electronic product such as a mobile product tends to be minimized and an area thereof tends to be increased. Therefore, the insulating layer part 10 may be designed and manufactured so as to correspond to these trends.

Chips (not shown) such as a power management integrated chip (PMIC) for supplying power may be mounted on the insulating layer 16 disposed at the uppermost portion of the insulating layer part 10. The chips may be connected to the connecting pads 12 through solder balls 30.

In addition, the respective insulating layers 16 may have circuit patterns formed thereon so as to be electrically connected to the solder balls 30, wherein the respective circuit patterns are electrically connected to the connecting pads.

The insulating layer part 10 may have the plurality of connecting pads 12 and non-connecting pads 14 formed thereat. The solder balls 30 may be mounted at the connecting pads 12 disposed at the uppermost side among the plurality of connecting pads 12. Particularly, the solder balls 30 are not mounted at all of the connecting pads, but may be restrictively mounted only at positions requiring electrical conduction.

The reinforcing vias 20 may be formed at the non-connecting pads 14 at which electrical conduction is not made. The reinforcing via 20 connects the non-connecting pads 14 disposed on and beneath of the insulating layer 16 to each other at a central portion of the non-connecting pad 14.

That is, the reinforcing via 20 is installed at the non-connecting pad 14 positioned at an edge at which the plurality of connecting pads 12 are formed to connect the non-connecting pads 14 disposed on and beneath of the insulating layer 16 to each other, thereby making it possible to firmly maintain the insulating layer 16 and the non-connecting pad 14 in the state in which they are closely adhered to each other.

In addition, a single reinforcing via 20 may be formed at a central portion of the non-connecting pad 14. However, it is preferable that a plurality of reinforcing vias 20 are formed in order to make fixing force uniform.

For example, the single reinforcing via 20 may be formed at the central portion of the non-connecting pad 14 and the plurality of reinforcing vias 20 may be formed at predetermined intervals in a circumferential direction based on the central portion.

Directions in which the reinforcing vias 20 are installed at the non-connecting padsl4 may be the same as or different from each other so that the reinforcing vias 20 may maintain a stable installation state with respect to external impact or warpage.

That is, all of the reinforcing vias 20 are processed using a laser beam in the same direction, such that the reinforcing via 20 disposed at the central portion and other reinforcing vias 20 adjacent thereto may have the same arrangement state. Alternatively, the reinforcing via 20 disposed at the central portion and other reinforcing vias 20 adjacent thereto may also be arranged in opposite directions.

Meanwhile, although not shown, the insulating layer 16 according to the exemplary embodiment of the present invention may include a copper clad laminate (CCL) (not shown) including an insulating material and copper foils formed on both surfaces of the insulating material. In addition, an embedded method in which a chip such as a multilayer ceramic capacitor (MLCC) is embedded in the CCL may also be applied.

In other words, the printed circuit board according to the exemplary embodiment of the present invention to which the embedded method is applied may be more effective particularly in the state in which the chip is embedded therein. The reason is that warpage of the board generated due to a difference in a coefficient of thermal expansion between the respective insulating layers and the chip in a process of embedding the chip may be effectively restricted by the plurality of reinforcing vias 20.

In the printed circuit board 100 according to the exemplary embodiment of the present invention configured as described above, in the case in which impact such as falling is applied after the chip is mounted in the insulating layer part 10 or in the case in which build-up of the insulating layers 16 having different coefficients of thermal expansion is performed, warpage is generated in the insulating layer part 10.

As the number of chips per a unit area is increased or as a thickness of the insulating layer part 10 is decreased, the warpage of the insulating layer part 10 is increased.

When the warpage is instantaneously generated in the insulating layer part 10 due to the impact applied from the outside or the warpage is generated in the insulating layer part 10 due to a difference in a coefficient of thermal expansion of the insulating layers 16 built-up in a manufacturing process, stress between the insulating layer part 10 and the solder balls 30 is increased, such that a crack may be generated in the solder balls 30.

Here, in the case in which a coupled state between the solder ball 30 and the connecting pad 12 is tighter than a coupled state between the connecting pad 12 and the insulating layer 16, the connecting pad 12 and the insulating layer 16 may be spaced apart from each other.

When impact or warpage stress is concentrated between the solder ball 30 and the connecting pad 12 or between the solder ball 30 and the insulating layer 16, a circuit pattern may be short-circuited. However, the reinforcing via 20 firmly supports the non-connecting pad 14 so that the non-connecting pad 14 is not easily separated from the insulating layer, in order to prevent the short-circuit of the circuit pattern.

That is, when the non-connecting pad 14 positioned at the edge of the insulating layer part 10 is firmly supported by the reinforcing via 20, the stress applied to the insulating layer 16 and the connecting pad 12 is decreased, such that the connecting pad 12 and the insulating layer 16 may be maintained in the state in which they are stably coupled to each other.

In addition, in the case in which the reinforcing via 20 is formed at the non-connecting pad 14 disposed at the edge of the insulating layer part 10, damage to the circuit pattern due to separation between the connecting pad 12 and the insulating layer 16 is prevented, thereby making it possible to significantly improve reliability of a product.

With the printed circuit board according to the exemplary embodiment of the present invention, the reinforcing vias are formed in non-connecting lands so that the insulating layer and the connecting pads may be maintained in the state in which they are tightly coupled to each other, thereby making it possible to increase durability and reliability of a product.

Hereinabove, although the printed circuit board according to the exemplary embodiment of the present invention has been described, the present invention is not limited thereto, but may be variously modified and altered by those skilled in the art.

What is claimed is:

1. A printed circuit board comprising:
an insulating layer part including circuit patterns and connecting lands having solder balls seated thereon and including a plurality of insulating layers;
a plurality of connecting pads and non-connecting pads formed at the insulating layer part; and
a plurality of reinforcing vias formed in the non-connecting pads and reinforcing a close adhesion state between the insulating layer part and the non-connecting pads.

2. The printed circuit board according to claim 1, wherein the reinforcing vias are formed at positions at which interlayer electrical conduction is not made among the plurality of connecting pads.

3. The printed circuit board according to claim 1, wherein the insulating layer part includes a copper clad laminate (CCL) including an insulating material and copper foils formed on both surfaces of the insulating material.

4. The printed circuit board according to claim 1, wherein the reinforcing via positioned at the center of the non-connecting pad and the reinforcing vias positioned along a circumferential surface of the non-connecting pad are formed in opposite directions.

5. The printed circuit board according to claim 1, wherein the reinforcing via positioned at the center of the non-connecting pad and the reinforcing vias positioned along a circumferential surface of the non-connecting pad are formed in the same direction.

6. The printed circuit board according to claim 1, wherein the reinforcing vias are formed at the non-connecting pads at which interlayer conduction is not made.

7. The printed circuit board according to claim 2, wherein the reinforcing vias are formed at the non-connecting pads at which interlayer conduction is not made.
